(19) United States
(12) Patent Application Publication
(10) Pub. No.: US 2009/0203219 A1
(43) Pub. Date: Aug. 13, 2009

(54) PLASMA ETCHING METHOD, PLASMA ETCHING APPARATUS AND COMPUTER-READABLE STORAGE MEDIUM

(75) Inventors: Shoichiro MATSUYAMA, Nirasaki City (JP); Masanobu Honda, Nirasaki City (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 12/369,961

(22) Filed: Feb. 12, 2009

Related U.S. Application Data
(60) Provisional application No. 61/047,968, filed on Apr. 25, 2008.

(30) Foreign Application Priority Data
Feb. 12, 2008 (JP) 2008-030079

(51) Int. Cl. H01L 21/3065

(52) U.S. Cl. 438/719; 156/345.24; 257/E21.218

(57) ABSTRACT

A plasma etching method includes etching a silicon layer formed on a substrate to be processed through a patterned mask layer by using a plasma of a processing gas. The processing gas contains at least a CF₃I gas, and during said etching the silicon layer, a radio frequency power is applied to a lower electrode mounting the substrate thereon such that a self-bias voltage Vdc for accelerating ions in the plasma is equal to or smaller than 200 V.

### FIELD OF THE INVENTION

The present invention relates to a plasma etching method for etching a silicon layer, which is an etching target layer formed on a substrate to be processed, by using a plasma of a processing gas.

### BACKGROUND OF THE INVENTION

Conventionally, in a manufacturing process of a semiconductor device, plasma etching is widely performed to etch a silicon layer such as a polysilicon layer and an amorphous silicon layer formed on a substrate to be processed by a plasma of a processing gas by using a photoresist as a mask.

Various processing gases are used in plasma etching. For example, a Cl₂ or HBr gas is used in plasma etching of silicon such as polysilicon, amorphous silicon and single crystalline silicon. However, since these gases have high corrosiveness, the plasma etching apparatus should be treated to have corrosion resistance against the corrosive gas, thereby increasing the manufacturing cost of the plasma etching apparatus.

Further, a so-called double patterning technology has been attempted to meet a demand for miniaturization of a circuit pattern in a recent semiconductor device. In the double patterning technology, plasma etching is continuously performed on a silicon oxide film, a silicon nitride film, amorphous silicon and the like. The plasma etching is required to be performed in the same processing chamber, for example, a processing chamber of a plasma etching apparatus for an insulating film.

Further, conventionally, a CF₃I gas has been known as a processing gas almost without causing any environmental problem. For example, a gaseous mixture containing CF₃I, HBr and O₂ is used to etch a metal polycide film having a high melting point in an ICP type plasma etching apparatus (see, e.g., Japanese Patent Laid-open Application No. H11-214357).

As described above, in plasma etching of silicon, since a highly corrosive gas is conventionally used, the plasma etching apparatus should be treated to have corrosion resistance against the corrosive gas, thereby increasing the manufacturing cost of the plasma etching apparatus. Further, in plasma etching of silicon, generally, it is required to maintain high selectivity of a silicon oxide film serving as a base film or a photoresist serving as a mask, to vertically form a sidewall of a line portion in etching of a pattern having lines and spaces, and to reduce an etching difference between a dense pattern portion and a sparse pattern portion.

### SUMMARY OF THE INVENTION

In view of the above, the present invention provides a plasma etching method capable of forming a desired pattern with good precision without using a highly corrosive processing gas, a plasma etching apparatus and a computer-readable storage medium.

In accordance with a first aspect of the present invention, there is provided a plasma etching method comprising: etching a silicon layer formed on a substrate to be processed through a patterned mask layer by using a plasma of a processing gas, wherein the processing gas contains at least a CF₃I gas, and during said etching the silicon layer, a radio frequency power is applied to a lower electrode mounting the substrate thereon such that a self-bias voltage Vdc for accelerating ions in the plasma is equal to or smaller than 200 V.

In the plasma etching method of the first aspect, the radio frequency power may have a frequency of 40 MHz or more.

In the plasma etching method of the first aspect, the patterned mask layer may have lines and spaces, and the patterned mask layer may include a dense pattern portion in which a ratio of a line width to a space width is 1/1 and a sparse pattern portion in which a ratio of a line width to a space width is 1/10 or less.

In accordance with a second aspect of the present invention, there is provided a plasma etching method comprising: etching a first layer formed on a silicon layer formed on a substrate to be processed by using a plasma of a first processing gas in a processing chamber, the first layer being formed of a material other than silicon, and then etching the silicon layer by using a plasma of a second processing gas in the processing chamber, wherein the second processing gas contains at least a CF₃I gas, and during said etching the silicon layer, a radio frequency power is applied to a lower electrode mounting the substrate thereon such that a self-bias voltage Vdc for accelerating ions in the plasma is equal to or smaller than 200 V.

In the plasma etching method of the second aspect, the radio frequency power may have a frequency of 40 MHz or more.

In accordance with a third aspect of the present invention, there is provided a plasma etching apparatus comprising: a processing chamber for accommodating therein a substrate to be processed; a processing gas supply unit for supplying a processing gas into the processing chamber; a plasma generating unit for converting the processing gas supplied from the processing gas supply unit into a plasma to process the substrate; and a controller for allowing the plasma etching method of the first and the second aspect to be performed in the processing chamber.

In accordance with a fourth aspect of the present invention, there is provided a computer-readable storage medium storing a control program executable on a computer, the control program controlling a plasma etching apparatus to perform the plasma etching method of the first and the second aspect.

In accordance with the aspects of the present invention, it is possible to provide a plasma etching method capable of forming a desired pattern with good precision without using a highly corrosive processing gas, a plasma etching apparatus and a computer-readable storage medium.

### BRIEF DESCRIPTION OF THE DRAWINGS

The objects and features of the present invention will become apparent from the following description of embodiments given in conjunction with the accompanying drawings, in which:

FIGS. 1A and 1B illustrate a cross sectional configuration of a semiconductor wafer in a plasma etching method in accordance with an embodiment of the present invention;

FIG. 2 illustrates a schematic configuration of a plasma etching apparatus in accordance with the embodiment of the present invention;

FIG. 3 illustrates scanning electron microscope (SEM) photographs showing an etching difference between experimental and comparison examples;

FIG. 4 illustrates ΔCD in a dense pattern portion and a sparse pattern portion in the experimental and comparison examples; and

FIG. 5 is a graph showing an electron density and Vdc in the experimental and comparison examples.

### DETAILED DESCRIPTION OF THE EMBODIMENTS

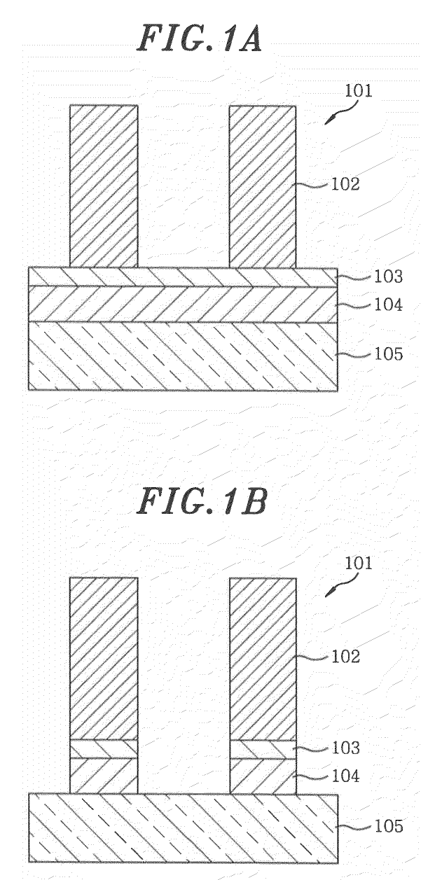

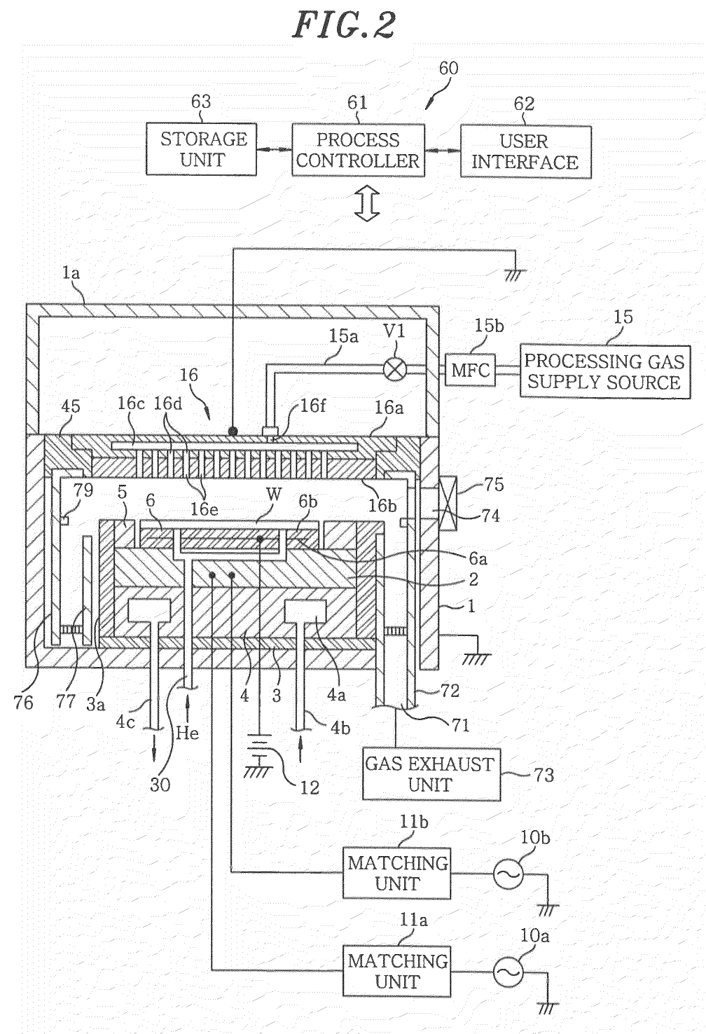

Hereinafter, embodiments of the present invention will be described in detail with reference to the accompanying drawings which form a part hereof. FIGS. 1A and 1B are enlarged views showing a cross sectional configuration of a semiconductor wafer serving as a substrate to be processed in a plasma etching method in accordance with an embodiment of the present invention. FIG. 2 illustrates a configuration of a plasma etching apparatus in accordance with the embodiment of the present invention. First, the configuration of the plasma etching apparatus will be described with reference to FIG. 2.

The plasma etching apparatus includes a processing chamber 1 which is airtightly sealed and electrically connected to a ground potential. The processing chamber 1 has a cylindrical shape and is made of, e.g., aluminum. A mounting table 2 serving as a lower electrode is provided in the processing chamber 1 to horizontally support the semiconductor wafer W serving as a substrate to be processed. The mounting table 2 is made of, e.g., aluminum and is supported by a support base 4 of a conductor through an insulating plate 3. A focus ring 5 is provided at an upper periphery of the mounting table 2. Further, a cylindrical inner wall member 3a made of, e.g., quartz is provided to surround the support base 4 of the mounting table 2.

The mounting table 2 is connected to a first RF power supply 10a via a first matching unit 11a and also connected to a second RF power supply 10b via a second matching unit 11b. The first RF power supply 10a for generating a plasma supplies a radio frequency power having a specific frequency (40 MHz or more, e.g., 40 MHz) to the mounting table 2. Further, the second RF power supply 10b for attracting ions supplies a radio frequency power having a specific frequency (13.56 MHz or less, e.g., 13.56 MHz) lower than that of the first RF power supply 10a to the mounting table 2. Meanwhile, a shower head 16 connected to a ground potential is provided above the mounting table 2 to face the mounting table 2 in parallel. The mounting table 2 and the shower head 16 serve as a pair of electrodes.

An electrostatic chuck 6 for electrostatic adsorption of the semiconductor wafer W is provided on an upper surface of the mounting table 2. The electrostatic chuck 6 is configured by embedding an electrode 6a in an insulator 6b. The electrode 6a is connected to a DC power supply 12. Accordingly, when a DC voltage is applied to the electrode 6a from the DC power supply 12, the semiconductor wafer W is adsorbed to the electrostatic chuck 6 by a Coulomb force.

A coolant path 4a is formed in the support base 4. The coolant path 4a is connected to a coolant inlet line 4b and a coolant outlet line 4c. The support base 4 and the mounting table 2 can be controlled to have a predetermined temperature by circulating an appropriate coolant, e.g., cooling water in the coolant path 4a. Further, a backside gas supply line 30 for supplying a cold heat transfer gas (backside gas) such as a helium gas to a backside of the semiconductor wafer W is formed to pass through the mounting table 2 and the like. The backside gas supply line 30 is connected to a backside gas supply source (not shown). By providing this configuration, the semiconductor wafer W, which is adsorptively held on the upper surface of the mounting table 2 by the electrostatic chuck 6, can be controlled to be maintained at a predetermined temperature.

The shower head 16 is provided at a ceiling wall of the processing chamber 1. The shower head 16 includes a main body portion 16a and an upper ceiling plate 16b forming an electrode plate. The shower head 16 is supported by a support member 45 provided at an upper portion of the processing chamber 1. The main body portion 16a is made of a conductive material, e.g., anodically oxidized aluminum and is configured to detachably support the upper ceiling plate 16b provided under the main body portion 16a.

A gas diffusion space 16c is formed inside the main body portion 16a. Gas through holes 16d are formed at the bottom portion of the main body portion 16a to be positioned under the gas diffusion space 16c. Further, gas inlet holes 16e are formed in the upper ceiling plate 16b corresponding to the gas through holes 16d to pass through the upper ceiling plate 16b in its thickness direction. By providing this configuration, a processing gas supplied to the gas diffusion space 16c is supplied to be dispersed in a shower pattern into the processing chamber 1 via the gas through holes 16d and the gas inlet holes 16e. Further, a line (not shown) for circulating a coolant is provided at the main body portion 16a or the like so as to cool the shower head 16 to a desired temperature during a plasma etching process.

A gas inlet port 16f for introducing a processing gas into the gas diffusion space 16c is formed at the main body portion 16a. The gas inlet port 16f is connected to one end of a gas supply line 15a. The other end of the gas supply line 15a is connected to a processing gas supply source 15 for supplying a processing gas for etching (etching gas). Further, the gas supply line 15a is provided with a mass flow controller (MFC) 15b and a valve V1 sequentially from its upstream side. Further, a gas containing at least a CF₃I gas, serving as a processing gas for plasma etching, is supplied to the gas diffusion space 16c from the processing gas supply source 15 through the gas supply line 15a. The gas is supplied to be dispersed in a shower pattern into the processing chamber 1 from the gas diffusion space 16c through the gas through holes 16d and the gas inlet holes 16e.

A cylindrical ground conductor 1a is provided at a higher position than a vertical position of the shower head 16 to extend upward from a sidewall of the processing chamber 1. The cylindrical ground conductor 1a has a ceiling wall at its upper portion.

A gas exhaust port 71 is formed at a bottom portion of the processing chamber 1. The gas exhaust port 71 is connected to a gas exhaust unit 73 via a gas exhaust pipe 72. The gas exhaust unit 73 has a vacuum pump which is operated such that the processing chamber 1 can be depressurized to a specific vacuum level. Meanwhile, a loading/unloading port 74 is provided at the sidewall of the processing chamber 1 such that the wafer W is loaded into or unloaded from the processing chamber 1 through the loading/unloading port 74. Further, a gate valve 75 for opening and closing the loading/unloading port 74 is provided at the loading/unloading port 74.

Reference numerals 76 and 77 of FIG. 2 designate detachable deposition shields. The deposition shield 76 is provided along an inner wall surface of the processing chamber 1. The deposition shield 76 prevents etching by-products (depositions) from being adhered to the processing chamber 1. A conductive member (GND block) 79, which is DC connected to ground, is provided at the deposition shield 76 at substantially the same position as the semiconductor wafer W, thereby preventing abnormal discharge.

An entire operation of the plasma etching apparatus having the above configuration is controlled by a controller 60. The controller 60 includes a process controller 61 having a CPU to control each component of the plasma etching apparatus, a user interface 62 and a storage unit 63.

The user interface 62 includes a keyboard for inputting commands, a display for displaying an operation status of the plasma etching apparatus or the like to allow a process manager to manage the plasma etching apparatus.

The storage unit 63 stores recipes including control programs (software) for implementing various processes in the plasma etching apparatus under control of the process controller 61, process condition data and the like. If necessary, as a certain recipe is retrieved from the storage unit 63 in accordance with an instruction inputted through the user interface 62 and executed in the process controller 61, a desired process is performed in the plasma etching apparatus under control of the process controller 61. Further, the recipes including control programs, process condition data and the like can be stored in and retrieved from a computer-readable storage medium such as a hard disk, a CD-ROM, a flexible disk and a semiconductor memory, or retrieved through an on-line connected via, for example, a dedicated line to another apparatus available all the time.

Next, steps for plasma etching silicon, such as polysilicon and amorphous silicon, formed on the semiconductor wafer W in the plasma etching apparatus having the above configuration will be described. First, the gate valve 75 is opened and, then, the semiconductor wafer W is loaded into the processing chamber 1 from the loading/unloading port 74 through a load-lock chamber (not shown) by using a transfer robot (not shown) to be mounted on the mounting table 2. Then, the transfer robot is retracted from the processing chamber 1 and the gate valve 75 is closed. Then, the processing chamber 1 is evacuated through the gas exhaust port 71 by using the vacuum pump of the gas exhaust unit 73.

After the processing chamber 1 is maintained to have a predetermined vacuum level, a specific processing gas (etching gas) is introduced into the processing chamber 1 from the processing gas supply source 15. When the processing chamber 1 is maintained at a predetermined pressure of, e.g., 3.99 Pa (30 mTorr), a radio frequency power having a frequency of, e.g., 40 MHz is supplied to the mounting table 2 from the first RF power supply 10a. Further, a radio frequency power having a frequency of, e.g., 13.56 MHz for attracting ions is supplied to the mounting table 2 from the second RF power supply 10b if necessary (not supplied in an experimental example to be described later). In this case, a specific DC voltage is applied to the electrode 6a of the electrostatic chuck 6 from the DC power supply 12, so that the semiconductor wafer W is adsorbed to the electrostatic chuck 6 by a Coulomb force.

In this case, when a radio frequency power is applied to the mounting table 2 serving as a lower electrode as described above, an electric field is formed between the shower head 16 serving as an upper electrode and the mounting table 2 serving as a lower electrode. Accordingly, discharge occurs in the processing space including the semiconductor wafer W, and a plasma of the processing gas is generated to thereby etch the silicon, such as polysilicon and amorphous silicon, formed on the semiconductor wafer W.

Further, when the etching process has been completed, supplies of the radio frequency power and the processing gas are stopped and the semiconductor wafer W is unloaded from the processing chamber 1 in a sequence opposite to the above-described sequence.

Next, a plasma etching method in accordance with the embodiment of the present invention will be described with reference to FIGS. 1A and 1B. FIGS. 1A and 1B illustrate enlarged views showing main parts of the semiconductor wafer W serving as a substrate to be processed in accordance with the embodiment of the present invention. As shown in FIG. 1A, a photoresist layer 102 (having a thickness of, e.g., 270 nm) patterned to have specific lines and spaces, an ARC (Anti-Reflection Coating) layer 103 (having a thickness of, e.g., 60 nm), a polysilicon layer 104 (having a thickness of, e.g., 80 nm) and a TEOS layer 105 (having a thickness of, e.g., 150 nm) are formed sequentially from top to bottom on a surface of a silicon substrate 101.

The semiconductor wafer W having the above structure is accommodated in the processing chamber 1 of the apparatus shown in FIG. 2 and mounted on the mounting table 2. In the state shown in FIG. 1A, the ARC layer 103 and the polysilicon layer 104 are sequentially etched by using the photoresist layer 102 as a mask to thereby form a pattern having lines and spaces.

First, plasma etching was performed on the ARC layer 103 for 40 seconds prior to an experimental example under conditions as follows:

Etching gas: CF₄/O₂=250/13 sccm

Pressure: 3.99 Pa (30 mTorr)

Frequency of radio frequency power: 40 MHz (400 W)/13.56 MHz (0 W)

Temperatures (top/sidewall/mounting portion): 60/60/30° C.

Backside helium pressures (center/periphery): 2000/2000 Pa.

Further, the pattern having lines and spaces included a dense pattern portion in which a ratio of a line width to a space width was 1/1 (line width/space width), a pattern portion of 1/2, a pattern portion of 1/3 and a sparse pattern portion of 1/10.

Then, plasma etching was performed on the polysilicon layer 104 for 30 seconds as an experimental example under conditions as follows:

Etching gas: CF₃I/Ar=100/100 sccm

Pressure: 3.99 Pa (30 mTorr)

Frequency of radio frequency power: 40 MHz (400 W)/13.56 MHz (0 W)

Temperatures (top/sidewall/mounting portion): 60/60/30° C.

Backside helium pressures (center/periphery): 2000/2000 Pa.

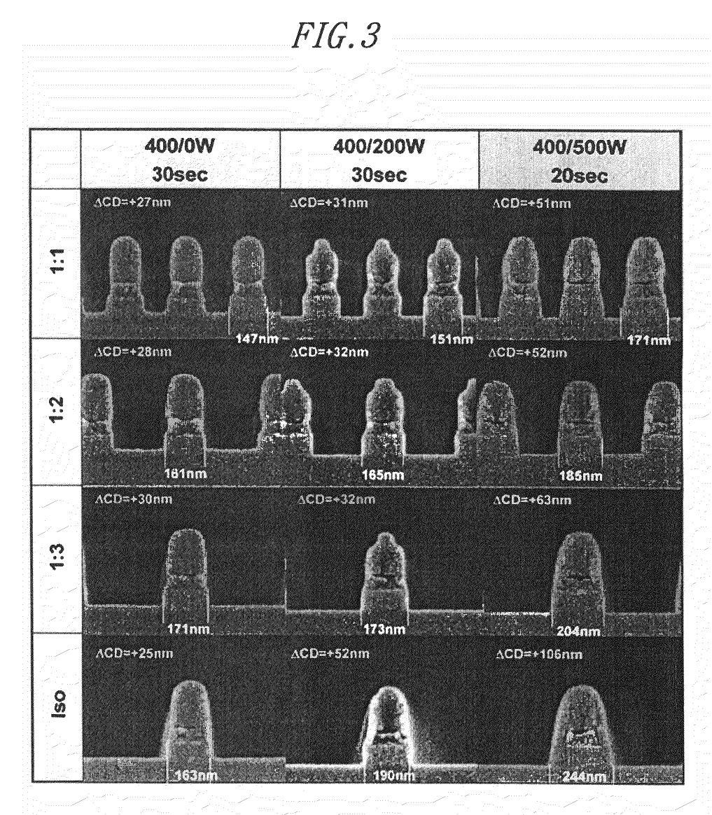

As a result, in the experimental example in which a bias power having a frequency of 13.56 MHz was 0 W, as shown in SEM enlarged photographs on the left of FIG. 3, the sidewall was etched in a substantially vertical and desirable shape in all portions of a dense pattern portion in which a ratio of a line width to a space width was 1/1 (line width/space width), a pattern portion of 1/2, a pattern portion of 1/3 and a sparse pattern portion of 1/10. Further, as a measurement result of line width variation ΔCD after etching of the ARC layer 103, a maximum difference of ΔCD was 5 nm (30−25), and both the dense pattern portion and the sparse pattern portion were etched uniformly. Further, selectivity of the TEOS layer 105 serving as a base film (etching rate of polysilicon/etching rate of TEOS) was 20 or more and selectivity of the photoresist (etching rate of polysilicon/etching rate of photoresist) was approximately 8.

Next, as a comparison example 1, plasma etching was performed on the polysilicon layer 104 under the same conditions as the experimental example except that a radio frequency power (bias power) having a low frequency of 13.56 MHz was 200 W. The SEM enlarged photographs after etching are shown in the middle of FIG. 3. Further, as a comparison example 2, plasma etching was performed on the polysilicon layer 104 under the same conditions as the experimental example except that a radio frequency power (bias power) having a low frequency of 13.56 MHz was 500 W and an etching time was 20 seconds. The SEM enlarged photographs after etching are shown on the right of FIG. 3.

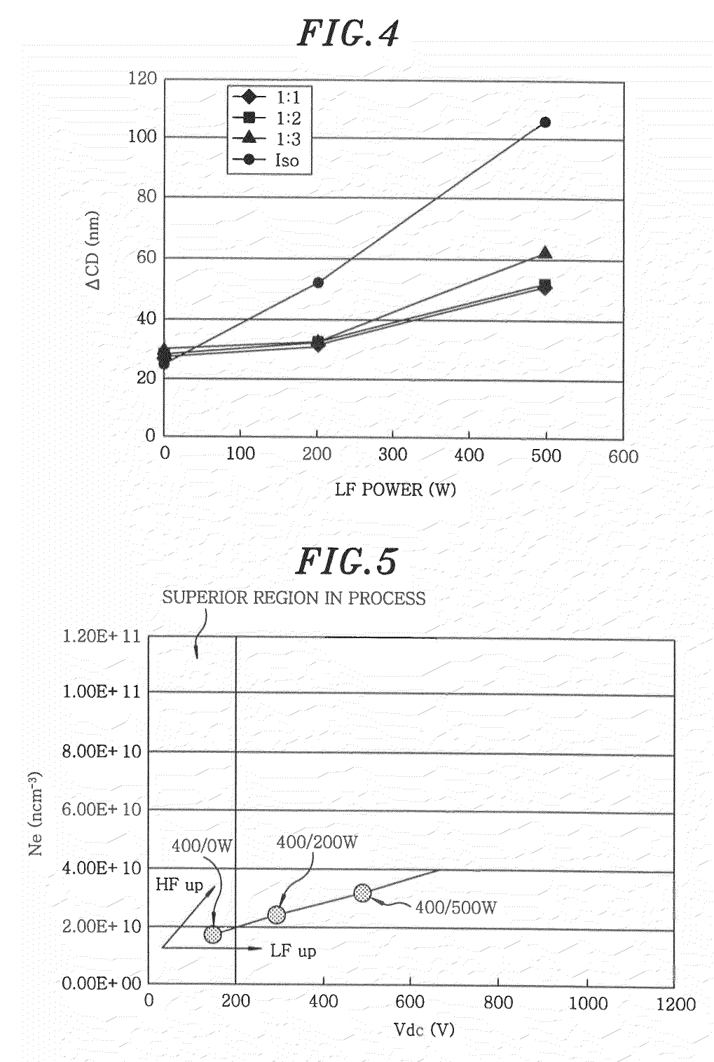

As shown in FIG. 3, in the comparison examples 1 and 2 having application of a radio frequency power (bias power) having a low frequency of 13.56 MHz, the sidewall was widened toward the end, particularly, in the sparse pattern portion, compared to the experimental example. Further, as a measurement result of line width variation ΔCD after etching of the ARC layer 103, a maximum difference of ΔCD was 21 nm (52−31) in the comparison example 1, and a maximum difference of ΔCD was 55 nm (106−51) in the comparison example 2. FIG. 4 illustrates a relationship between ΔCD and a radio frequency power having a low frequency (LF power). As shown in FIG. 4, in application of a radio frequency power having a low frequency (LF power), ΔCD in the sparse pattern portion increased and a difference of ΔCD between the sparse pattern portion and the dense pattern portion also increased. That is, a nonuniform etching shape was obtained in the dense pattern portion and the sparse pattern portion.

As for the reason, it is assumed that in application of a radio frequency power (LF power) having a low frequency of 13.56 MHz or less, a self-bias voltage Vdc for accelerating ions in the plasma increases to thereby increase an amount of depositions adhered to the sidewall of the pattern by sputtering in the sparse pattern portion. FIG. 5 shows a relationship between an electron density and Vdc in the experimental example and comparison examples 1 and 2. In the experimental example, in application of radio frequency power of 40 MHz (400 W)/13.56 MHz (0 W), the self-bias voltage Vdc was equal to or smaller than 200 V. Meanwhile, in the comparison example 1, in application of radio frequency power of 40 MHz (400 W)/13.56 MHz (200 W), the self-bias voltage Vdc exceeded 200 V to be about 300 V. In the comparison example 2, in application of radio frequency power of 40 MHz (400 W)/13.56 MHz (500 W), the self-bias voltage Vdc exceeded 200 V to be about 500 V.

Further, selectivity of the TEOS layer 105 (etching rate of polysilicon/etching rate of TEOS) as well as the etching shape tended to be deteriorated in the comparison examples 1 and 2 compared to the experimental example. That is, after etching, a film reduction amount of the TEOS layer 105 serving as a base was measured and calculated per unit time to be 7 nm/min in the experimental example, while it was 36 nm/min in the comparison example 1 and 112 nm/min in the comparison example 2.

As described above, when plasma etching is performed on silicon by using a gas containing a CF₃I gas as an etching gas, a radio frequency power is applied to the mounting table (lower electrode) 2 such that the self-bias voltage Vdc is equal to or smaller than 200 V. Accordingly, it is possible to etch the sidewall in a substantially vertical and desirable shape and achieve uniform etching in both the dense pattern portion and the sparse pattern portion. Further, selectivity of TEOS serving as a base and selectivity of the photoresist can be maintained at desired levels. In the experimental example, in application of radio frequency power of 40 MHz (400 W)/13.56 MHz (0 W), the self-bias voltage Vdc was made to be equal to or smaller than 200 V. However, in a case using a radio frequency power of 40 MHz, when a power applied to the mounting table (lower electrode) 2 increases, the self-bias voltage Vdc may exceed 200 V. Thus, in a case using a radio frequency power of 40 MHz, preferably, a power of about 400 W is applied to the mounting table 2 serving as a lower electrode. Further, of course, if Vdc does not exceed 200 V, a bias power may be applied.

Further, although a gaseous mixture containing CF₃I and Ar was used in the experimental example, since CF₃I has low corrosiveness, an anti-corrosion method for the etching apparatus is unnecessary and plasma etching can be performed in the plasma etching apparatus for etching an insulating film. Accordingly, in double patterning or the like, plasma etching of silicon can be performed in a processing chamber in which plasma etching has been performed on a film made of materials other than silicon, for example, SiO₂, SiN, SiC, SiCN, W, TiN, Al₂O₃, Y₂O₃ and HfO₂, an organic film or the like.

As described above, in accordance with the embodiment of the present invention, it is possible to form a desired pattern with good precision without using a highly corrosive processing gas. Further, the present invention may be modified without being limited to the above-described embodiment. For example, the plasma etching apparatus may employ various plasma etching apparatuses such as an upper-and-lower plate dual frequency application type plasma etching apparatus or a lower plate single frequency application type plasma etching apparatus without being limited to a parallel plate type and lower plate dual frequency application type plasma etching apparatus shown in FIG. 2. Further, although a gaseous mixture containing CF₃I and Ar is used in the embodiment, the gaseous mixture serving as an etching gas may contain a different type of rare gas, N₂, O₂ or the like. Further, a HBr gas or a Cl₂ gas may be added to the gaseous mixture in a case using an apparatus having corrosion resistance.

While the invention has been shown and described with respect to the embodiments, it will be understood by those skilled in the art that various changes and modifications may be made without departing from the scope of the invention as defined in the following claims.

What is claimed is:

1. A plasma etching method comprising:
etching a silicon layer formed on a substrate to be processed through a patterned mask layer by using a plasma of a processing gas,
wherein the processing gas contains at least a CF₃I gas, and
during said etching the silicon layer, a radio frequency power is applied to a lower electrode mounting the substrate thereon such that a self-bias voltage Vdc for accelerating ions in the plasma is equal to or smaller than 200 V.

2. The plasma etching method of claim 1, wherein the radio frequency power has a frequency of 40 MHz or more.

3. The plasma etching method of claim 1, wherein the patterned mask layer has lines and spaces, and the patterned mask layer includes a dense pattern portion in which a ratio of a line width to a space width is 1/1 and a sparse pattern portion in which a ratio of a line width to a space width is 1/10 or less.

4. A plasma etching method comprising:
etching a first layer formed on a silicon layer formed on a substrate to be processed by using a plasma of a first processing gas in a processing chamber, the first layer being formed of a material other than silicon, and then etching the silicon layer by using a plasma of a second processing gas in the processing chamber,
wherein the second processing gas contains at least a CF₃I gas, and
during said etching the silicon layer, a radio frequency power is applied to a lower electrode mounting the substrate thereon such that a self-bias voltage Vdc for accelerating ions in the plasma is equal to or smaller than 200 V.

5. The plasma etching method of claim 4, wherein the radio frequency power has a frequency of 40 MHz or more.

6. A plasma etching apparatus comprising:
a processing chamber for accommodating therein a substrate to be processed;
a processing gas supply unit for supplying a processing gas into the processing chamber;
a plasma generating unit for converting the processing gas supplied from the processing gas supply unit into a plasma to process the substrate; and
a controller for allowing the plasma etching method described in claim 1 to be performed in the processing chamber.

7. A plasma etching apparatus comprising:
a processing chamber for accommodating therein a substrate to be processed;
a processing gas supply unit for supplying a processing gas into the processing chamber;
a plasma generating unit for converting the processing gas supplied from the processing gas supply unit into a plasma to process the substrate; and
a controller for allowing the plasma etching method described in claim 4 to be performed in the processing chamber.

8. A computer-readable storage medium storing a control program executable on a computer, the control program controlling a plasma etching apparatus to perform the plasma etching method described in claim 1.

9. A computer-readable storage medium storing a control program executable on a computer, the control program controlling a plasma etching apparatus to perform the plasma etching method described in claim 4.
